(19) United States
(12) Patent Application Publication
(10) Pub. No.: US 2026/0020442 A1
(43) Pub. Date: Jan. 15, 2026

(54) DISPLAY DEVICE

(71) Applicant: Japan Display Inc., Tokyo (JP)

(72) Inventors: Daichi HOSOKAWA, Tokyo (JP); Sho YANAGISAWA, Tokyo (JP); Hideyuki TAKAHASHI, Tokyo (JP); Yasuhito ARUGA, Tokyo (JP)

(73) Assignee: Japan Display Inc., Tokyo (JP)

(21) Appl. No.: 19/263,760

(22) Filed: Jul. 9, 2025

(30) Foreign Application Priority Data
Jul. 11, 2024 (JP) 2024-111846

(51) Int. Cl. H10K 59/122

(52) U.S. Cl. CPC H10K 59/122

(57) ABSTRACT

According to one embodiment, a display device includes an inorganic insulating layer, an organic insulating layer disposed on the inorganic insulating layer, a rib layer disposed above the organic insulating layer, a lower electrode disposed on the organic insulating layer in a display area, an organic layer disposed on the lower electrode, an upper electrode covering the organic layer, a first partition, and a base disposed between the inorganic insulating layer and the organic insulating layer in a peripheral area, and having identification information, and the rib layer includes a first aperture that overlaps the base in the peripheral area.

### CROSS-REFERENCE TO RELATED APPLICATION

This application is based upon and claims the benefit of priority from Japanese Patent Application No. 2024-111846, filed Jul. 11, 2024, the entire contents of which are incorporated herein by reference.

### FIELD

Embodiments described herein relate generally to a display device.

### BACKGROUND

In recent years, display devices using organic light-emitting diodes (OLEDs) as display elements have been put into practical use. In such display devices, there is a need for technology to suppress the deterioration of reliability.

### BRIEF DESCRIPTION OF THE DRAWINGS

FIG. 1 is a diagram showing a configuration example of a display device.

FIG. 2 is a diagram showing an example of layout of subpixels.

FIG. 3 is a cross-sectional view schematically showing the display device taken along the line 3-3 in FIG. 2.

FIG. 4 is a cross-sectional view showing a configuration example of the display device taken along the line 4-4 in FIG. 1.

FIG. 5 is a plan view showing a configuration example of a peripheral area.

FIG. 6 is a cross-sectional view schematically showing the display device taken along the line 6-6 in FIG. 5.

FIG. 7A is a cross-sectional view schematically showing a processing step in manufacturing of the display device.

FIG. 7B is a cross-sectional view schematically showing another processing step in the manufacturing of the display device.

FIG. 7C is a cross-sectional view schematically showing still another processing step in the manufacturing of the display device.

FIG. 7D is a cross-sectional view schematically showing still another processing step in the manufacturing of the display device.

FIG. 7E is a cross-sectional view schematically showing still another processing step in the manufacturing of the display device.

FIG. 7F is a cross-sectional view schematically showing still another processing step in the manufacturing of the display device.

FIG. 7G is a cross-sectional view schematically showing still another processing step in the manufacturing of the display device.

FIG. 7H is a cross-sectional view schematically showing still another processing step in the manufacturing of the display device.

FIG. 8A is a cross-sectional view schematically showing still another processing step in the manufacturing of the display device.

FIG. 8B is a cross-sectional view schematically showing still another processing step in the manufacturing of the display device.

FIG. 8C is a cross-sectional view schematically showing still another processing step in the manufacturing of the display device.

FIG. 8D is a cross-sectional view schematically showing still another processing step in the manufacturing of the display device.

FIG. 8E is a cross-sectional view schematically showing still another processing step in the manufacturing of the display device.

FIG. 8F is a cross-sectional view schematically showing still another processing step in the manufacturing of the display device.

FIG. 9 is a cross-sectional view schematically showing a processing step in the manufacturing of the display device.

FIG. 10 is a cross-sectional view showing a display device of a comparative example.

FIG. 11 is a plan view showing other configuration example of the peripheral area shown in FIG. 5.

FIG. 12 is a cross-sectional view schematically showing the display device taken along the line 12-12 in FIG. 11.

FIG. 13 is a cross-sectional view showing another configuration example of the display device shown in FIG. 3.

FIG. 14 a plan view showing a configuration example of a peripheral area of the display device shown in FIG. 13.

FIG. 15 is a cross-sectional view schematically showing the display device taken along the line 15-15 in FIG. 14.

FIG. 16 is a cross-sectional view showing a configuration example of the display device shown in FIG. 4.

FIG. 17 is a diagram showing one configuration example of a peripheral area of the display device shown in FIG. 16.

FIG. 18 is a cross-sectional view schematically showing the display device taken along the line 18-18 in FIG. 17.

FIG. 19 is a diagram showing another configuration example of the peripheral area shown in FIG. 5.

FIG. 20 is a cross-sectional view schematically showing the display device taken along the line 20-20 in FIG. 19.

FIG. 21 is a cross-sectional view showing another configuration example of the peripheral area shown in FIG. 19.

FIG. 22 is a cross-sectional view schematically showing the display device taken along the line 22-22 in FIG. 21.

### DETAILED DESCRIPTION

In general, according to one embodiment, a display device comprises a substrate, an inorganic insulating layer disposed above the substrate and disposed over a display area which displays images and a peripheral area on an outer side of the display area, an organic insulating layer disposed on the inorganic insulating layer, a rib layer disposed above the organic insulating layer and formed of an inorganic material, a lower electrode disposed on the organic insulating layer in the display area and including a peripheral portion covered by the rib layer, an organic layer including a light emitting layer disposed on the lower electrode, an upper electrode covering the organic layer, a first partition including a first lower portion disposed on the rib layer and a first upper portion protruding from a side surface of the first lower portion in the display area, and a base disposed between the inorganic insulating layer and the organic insulating layer in the peripheral area, and having identification information, and the rib layer includes a first aperture that overlaps the base in the peripheral area in plan view.

Further, according to another embodiment, a display device comprises a substrate, an inorganic insulating layer disposed above the substrate and disposed over a display area which displays images and a peripheral area on an outer side of the display area, an organic insulating layer disposed on the inorganic insulating layer, a rib layer disposed above the organic insulating layer and formed of an inorganic material, a lower electrode disposed on the organic insulating layer in the display area and including a peripheral portion covered by the rib layer, an organic layer including a light emitting layer disposed on the lower electrode, an upper electrode covering the organic layer, a first partition including a first lower portion disposed on the rib layer and a first upper portion protruding from a side surface of the first lower portion in the display area, and a protective layer disposed above the rib layer in the peripheral area and having identification information.

With configurations such as described above, it is possible to provide a display device which can suppress the decrease in reliability.

An embodiment will be described hereinafter with reference to the accompanying drawings.

Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

Note that, in order to make the descriptions more easily understandable, some of the drawings illustrate an X axis, a Y axis and a Z axis orthogonal to each other. A direction along the X axis is referred to as a first direction X, a direction along the Y axis is referred to as a second direction Y and a direction along the Z axis is referred to as a third direction Z. Further, viewing the constitutional elements parallel to the Z direction is referred to as plan view.

The display device according to this embodiment is an organic electroluminescence display device comprising organic light-emitting diodes (OLEDs) as display elements, and may be incorporated into televisions, personal computers, automotive devices, tablet terminals, smartphones, mobile phone terminals, and the like.

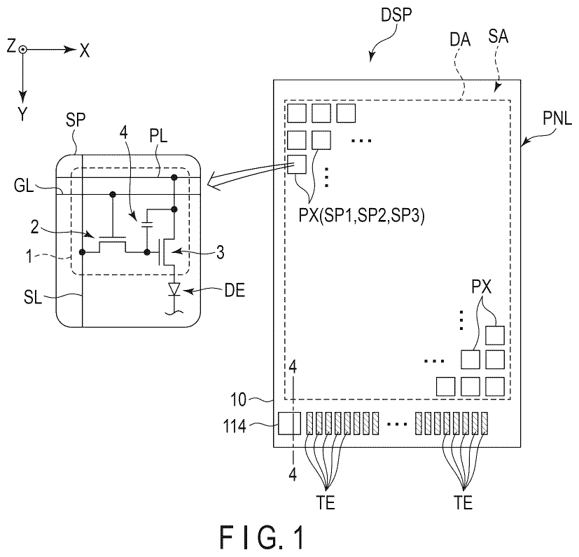

FIG. 1 is a diagram showing a configuration example of a display device DSP.

The display device DSP comprises a display panel PNL including a display area DA which displays images and a peripheral area SA located on an outer side of the display area DA, on an insulating substrate 10. The substrate 10 may be glass or a flexible resin film.

In this embodiment, the shape of the substrate 10 in plan view is rectangular. Note here that the shape of the substrate 10 in plan view is not limited to rectangular, and may be square, circular, elliptical, or some other shape.

The display area DA comprises a plurality of pixels PX arranged in a matrix along the first direction X and the second direction Y. Each of the pixels PX includes a plurality of subpixels SP. For example, the pixels PX each include a subpixel SP1 of a first color, a subpixel SP2 of a second color, and a subpixel SP3 of a third color. The first color, second color, and third color are mutually different colors. The pixels PX each may include a subpixel of some other color such as white together with the subpixels SP1, SP2, and SP3 or in place of any of the subpixels SP1, SP2, and SP3.

The subpixels SP each comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are switching elements formed, for example, by thin-film transistors.

A gate electrode of the pixel switch 2 is connected to a respective scanning line GL. One of a source electrode and a drain electrode of the pixel switch 2 is connected to a respective signal line SL, and the other is connected to the gate electrode of the drive transistor 3 and the capacitor 4. In the drive transistor 3, one of the source electrode and drain electrode is connected to a power supply line PL and the capacitor 4, and the other is connected to the anode of the display element DE.

Note that the configuration of the pixel circuit 1 is not limited to that of the example shown in the figure. For example, the pixel circuit 1 may include more thin-film transistors and capacitors.

The display element DE is an organic light-emitting diode (OLED) functioning as a light-emitting element and may as well be referred to as an organic EL element.

The peripheral area SA has a plurality of terminals TE arranged along a single direction. In the example illustrated, these terminals TE are arranged along the first direction X, and each of the terminals TE extends out in the second direction Y. But the embodiment is not limited to such a configuration. The terminals TE having such a configuration are electrically connected to, for example, a flexible printed circuit board or an IC chip.

The peripheral area SA further includes a base 114 having identification information 200 for the display device DSP. In the example illustrated, the multiple terminals TE and the base 114 are arranged along the first direction X. The identification information 200 is, for example, information necessary for managing the product, such as the product's manufacturing number or lot number. The identification information 200 is, for example, formed as a two-dimensional code, and the information can be obtained by reading the identification information 200 with a scanner or the like.

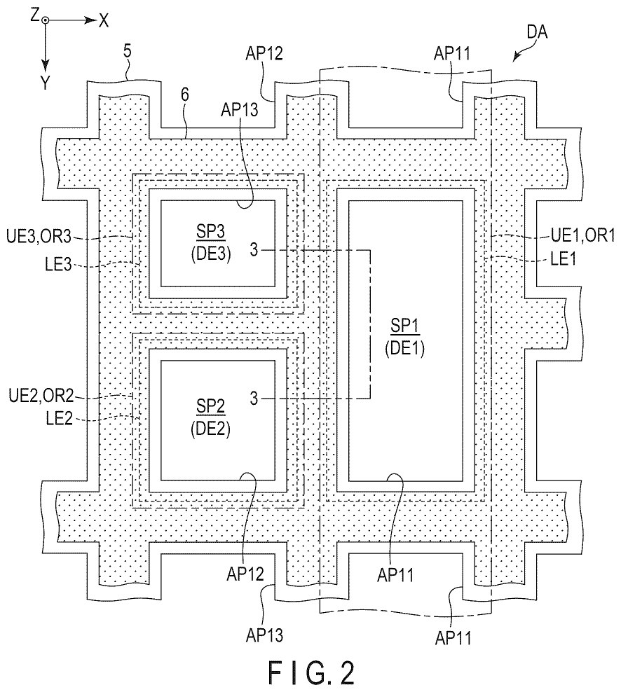

FIG. 2 is a diagram showing an example of a layout of the subpixels SP1, SP2, and SP3.

In the example illustrated, the subpixel SP2 and the subpixel SP3 are arranged along the second direction Y. The subpixel SP1 and the subpixel SP2 are arranged along the first direction X, and the subpixel SP1 and the subpixel SP3 are arranged along the first direction X.

When the subpixels SP1, SP2, and SP3 are arranged in such a layout, the display area DA is constituted by columns in which the subpixels SP2 and subpixels SP3 are alternately arranged along the second direction Y, and columns in which multiple subpixels SP1 are arranged along the second direction Y. These columns are arranged alternately along the first direction X.

Note that the layout of the subpixels SP1, SP2, and SP3 is not limited to that of the example shown in FIG. 2. As some other example, the subpixels SP1, SP2, and SP3 in each pixel PX may be arranged sequentially along the first direction X.

The display area DA includes a rib layer 5 and a partition 6. The rib layer 5 has apertures AP11, AP12, and AP13 in the subpixels SP1, SP2, and SP3, respectively.

The partition 6 overlaps the rib layer 5 in plan view. The partition 6 is formed in a lattice pattern in which cells respectively surround the apertures AP11, AP12, and AP13. It may as well be described as that the partition 6 have apertures in the subpixels SP1, SP2, and SP3, respectively, as in the case of the rib layer 5. The partition 6 is electrically conductive and is electrically connected to a terminal TE of a common potential among the multiple terminals TE shown in FIG. 1.

The subpixels SP1, SP2, and SP3 serve as display elements DE, which comprises display elements DE1, DE2, and DE3, respectively.

The display element DE1 of the subpixel SP1 comprises a lower electrode LE1, an upper electrode UE1, and an organic layer OR1, each overlapping the aperture AP11. The peripheral portion of the lower electrode LE1 is covered by the rib layer 5. The lower electrode LE1, the organic layer OR1, and the upper electrode UE1 are surrounded by the partition 6 in plan view. The respective peripheral portions of the organic layer OR1 and the upper electrode UE1 overlap the rib layer 5 in plan view. The organic layer OR1 includes, for example, a light-emitting layer that emits light in a blue wavelength region.

The display element DE2 of the subpixel SP2 comprises a lower electrode LE2, an upper electrode UE2, and an organic layer OR2, each overlapping with the aperture AP12. The peripheral portion of the lower electrode LE2 is covered by the rib layer 5. The lower electrode LE2, the organic layer OR2, and the upper electrode UE2 are surrounded by the partition 6 in plan view. The respective peripheral portions of the organic layer OR2 and the upper electrode UE2 overlap the rib layer 5 in plan view. The organic layer OR2 includes a light-emitting layer that emits light in, for example, a green wavelength region.

The display element DE3 of the subpixel SP3 comprises a lower electrode LE3, an upper electrode UE3, and an organic layer OR3, each overlapping the aperture AP13. The peripheral portion of the lower electrode LE3 is covered by the rib layer 5. The lower electrode LE3, the organic layer OR3, and the upper electrode UE3 are surrounded by the partition 6 in plan view. The respective peripheral portions of the organic layer OR3 and the upper electrode UE3 overlap the rib layer 5 in plan view. The organic layer OR3 includes a light-emitting layer that emits light in, for example, a red wavelength region.

In the example illustrated, the outer shapes of the lower electrodes LE1, LE2, and LE3 are drawn with dashed lines, and the outer shapes of the organic layers OR1, OR2, and OR3, and the upper electrodes UE1, UE2, and UE3 are drawn with alternate long and short dash lines. Note that the outer shapes of the lower electrodes, organic layers, and upper electrodes shown in the figure do not necessarily reflect their actual shapes.

The lower electrodes LE1, LE2, and LE3 correspond to the anodes of the display elements DE. The upper electrodes UE1, UE2, and UE3 correspond to the cathodes or common electrodes of the display elements DE and are in contact with the partition 6.

The lower electrode LE1 is electrically connected to the pixel circuit 1 of the subpixel SP1. The lower electrode LE2 is electrically connected to the pixel circuit 1 of the subpixel SP2. The lower electrode LE3 is electrically connected to the pixel circuit 1 of the subpixel SP3.

In the example illustrated, the area of the aperture AP11, the area of the aperture AP12, and the area of the aperture AP13 are different from each other. The area of the aperture AP11 is greater than the area of the aperture AP12, and the area of the aperture AP12 is greater than the area of the aperture AP13. In other words, the area of the lower electrode LE1 exposed from the aperture AP11 is greater than the area of the lower electrode LE2 exposed from the aperture AP12, and the area of the lower electrode LE2 exposed from the aperture AP12 is greater than the area of the lower electrode LE3 exposed from the aperture AP13.

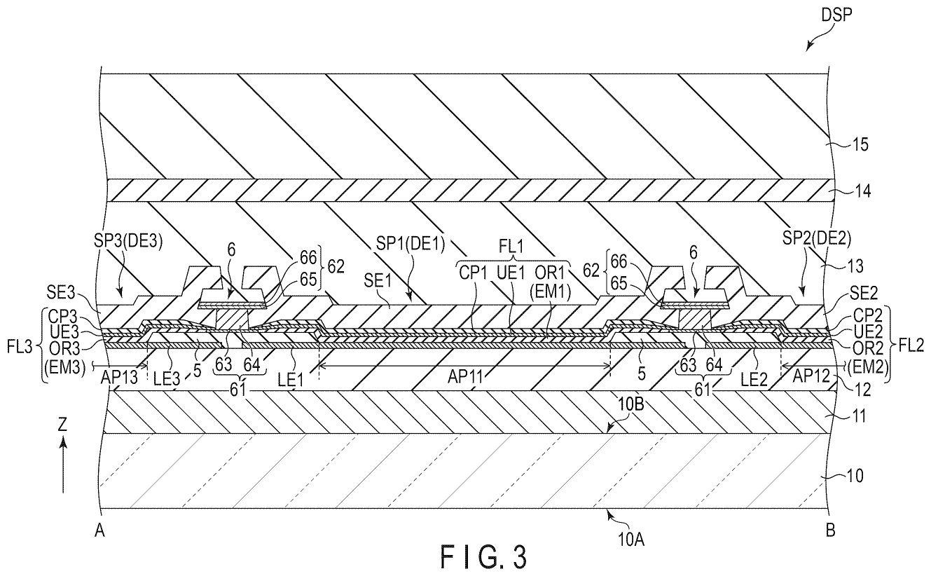

FIG. 3 is a cross-sectional view schematically showing the display device DSP taken along the line 3-3 in FIG. 2.

The substrate 10 has a main surface (lower surface) 10A and a main surface (upper surface) 10B on an opposite side to the main surface 10A. The main surfaces 10A and 10B are surfaces that are substantially parallel to the X-Y plane. The circuit layer 11 is disposed on the main surface 10B of the substrate 10. The circuit layer 11 includes various circuits such as the pixel circuit 1 and the like shown in FIG. 1, and various wiring lines such as scanning lines GL, signal lines SL, and power lines PL. The circuit layer 11 is covered by the organic insulating layer 12. The organic insulating layer 12 planarizes the unevenness caused by the circuit layer 11.

The lower electrodes LE1, LE2, and LE3 are disposed on the organic insulating layer 12 so as to be spaced apart from each other. The rib layer 5 is disposed on the organic insulating layer 12 and the lower electrodes LE1, LE2, and LE3. The aperture AP11 of the rib layer 5 overlaps the lower electrode LE1, the aperture AP12 overlaps the lower electrode LE2, and the aperture AP13 overlaps the lower electrode LE3.

The peripheral portions of the lower electrodes LE1, LE2, and LE3 are covered by the rib layer 5. The lower electrodes LE1, LE2, and LE3 are connected to the respective pixel circuits 1 of the subpixels SP1, SP2, and SP3 via contact holes made in the organic insulating layer 12. Note that the contact holes in the organic insulating layer 12 are omitted in the illustration of FIG. 3.

The partition 6 includes a lower portion 61 having conductivity and disposed on the rib layer 5 and an upper portion 62 disposed on the lower portion 61. The upper portion 62 has a width larger than that of the lower portion 61. Both end portions of the upper portion 62 protrude beyond the respective side surfaces of the lower portion 61. Such a shape of the partition 6 is referred to as an overhang shape.

In the example illustrated, the lower portion 61 includes a bottom layer 63 disposed on the rib layer and an axis layer 64 disposed on the bottom layer 63. For example, the bottom layer 63 is formed thinner than the axis layer 64. Both end portions of the bottom layer 63 protrude from the respective side surfaces of the axis layer 64.

The upper portion 62 includes a first thin film 65 disposed on the axial layer 64 and a second thin film 66 disposed on the first thin film 65. Both end portions of the first thin film 65 and the second thin film 66 protrude from the respective side surfaces of the axial layer 64.

The organic layer OR1 is brought into contact with the lower electrode LE1 via the aperture AP11 so as to cover the lower electrode LE1 exposed from the aperture AP11, and a peripheral portion thereof is located on the rib layer 5. The upper electrode UE1 covers the organic layer OR1 and is brought into contact with the lower portion 61.

The organic layer OR2 is brought into contact with the lower electrode LE2 via the aperture AP12 so as to cover the lower electrode LE2 exposed from the aperture AP12, and a peripheral portion thereof is located on the rib layer 5. The upper electrode UE2 covers the organic layer OR2 and is brought into contact with the lower portion 61.

The organic layer OR3 is brought into contact with the lower electrode LE3 via the aperture AP13 so as to cover the lower electrode LE3 exposed from the aperture AP13, and a peripheral portion thereof is located on the rib layer 5. The upper electrode UE3 covers the organic layer OR3 and is brought into contact with the lower portion 61.

In the example illustrated, the subpixel SP1 has a cap layer CP1 and a sealing layer SE1, the subpixel SP2 has a cap layer CP2 and a sealing layer SE2, and the subpixel SP3 has a cap layer CP3 and a sealing layer SE3. The cap layers CP1, CP2, and CP3 serve as optical adjustment layers to improve the light extraction efficiency of light emitted from the organic layers OR1, OR2, and OR3, respectively. Note that the cap layers CP1, CP2, and CP3 may be omitted.

The cap layer CP1 is disposed on the upper electrode UE1.

The cap layer CP2 is disposed on the upper electrode UE2.

The cap layer CP3 is disposed on the upper electrode UE3.

The sealing layer SE1 is disposed on the cap layer CP1, is brought into contact with the partition 6, and continuously covers the components of the subpixel SP1.

The sealing layer SE2 is disposed on the cap layer CP2, is brought into contact with the partition 6, and continuously covers the components of the subpixel SP2.

The sealing layer SE3 is disposed on the cap layer CP3, is brought into contact with the partition 6, and continuously covers the components of the subpixel SP3.

In the following description, a multilayer body comprising the organic layer OR1, the upper electrode UE1, and the cap layer CP1 is referred to as a multilayer stacked film FL1, a multilayer body comprising the organic layer OR2, the upper electrode UE2, and the cap layer CP2 is referred to as a multilayer stacked film FL2, and a multilayer body comprising the organic layer OR3, the upper electrode UE3, and the cap layer CP3 is referred to as a multilayer stacked film FL3.

End portions of the sealing layers SE1, SE2, and SE3 are each located on the partition 6. In the example illustrated, the sealing layer SE1 on the partition 6 between the subpixels SP1 and SP2 is spaced apart from the sealing layer SE2 on the partition 6. Further, the sealing layer SE1 on the partition 6 between the subpixels SP1 and SP3 is spaced apart from the sealing layer SE3 on the partition 6.

In the example illustrated, gaps are formed respectively between the sealing layers SE1, SE2, and SE3 and the upper portions 62 of the partition 6. Although not shown, the multilayer stacked film FL1, FL2, or FL3 may be disposed in at least part of these gaps.

The partition 6 and the sealing layers SE1, SE2, and SE3 are covered by a resin layer 13. The resin layer 13 fills the cavity between the sealing layers SE1, SE2, and SE3 and the partition 6. The resin layer 13 is covered by a sealing layer 14. The sealing layer 14 is covered by a resin layer 15.

The rib layer 5, and the sealing layers SE1, SE2, and SE3, and the sealing layer 14 are formed, for example, from an inorganic insulating material such as silicon nitride (SiNx), silicon oxide (SiOx), silicon nitride oxide (SiON), or aluminum oxide (Al₂O₃).

The lower portion 61 of the partition 6 is formed of a conductive material and is electrically connected to the upper electrodes UE1, UE2, and UE3. The bottom layer 63 is formed, for example, from a titanium-based material such as titanium or a titanium compound. The axis layer 64 is formed of a material different from that of the bottom layer 63 and the upper portion 62, that is, for example, an aluminum-based material such as aluminum or aluminum compound.

The upper portion 62 of the partition 6 is formed, for example, from a conductive material, but may also be formed of an insulating material. The upper portion 62 is formed of a material different from that of the lower portion 61. The first thin film 65 is formed, for example, from a titanium-based material such as titanium or a titanium compound. The second thin film 66 is formed, for example, from an oxide conductive material such as indium tin oxide (ITO).

The lower electrodes LE1, LE2, and LE3 are each a multilayer body comprising a transparent layer formed, for example, from an oxide conductive material such as indium tin oxide (ITO) and a reflective layer formed of a metal material such as silver. In one example, the lower electrodes LE1, LE2, and LE3 are each a multilayer body comprising a reflective layer between a pair of transparent layers.

The organic layer OR1 includes a light emitting layer EM1. The organic layer OR2 includes a light emitting layer EM2. The organic layer OR3 includes a light emitting layer EM3. The light emitting layers EM1, EM2, and EM3 are formed from materials different from each other. For example, the light-emitting layer EM1 is formed from a material that emits light in a blue wavelength region, the light-emitting layer EM2 is formed from a material that emits light in a green wavelength region, and the light-emitting layer EM3 is formed from a material that emits light in a red wavelength region. Further, each of the organic layers OR1, OR2, and OR3 includes multiple functional layers such as a hole injection layer, a hole transport layer, an electron blocking layer, a hole blocking layer, an electron transport layer, and an electron injection layer.

The upper electrodes UE1, UE2, and UE3 are formed, for example, from a metal material such as an alloy of magnesium and silver (MgAg).

The cap layers CP1, CP2, and CP3 are each a multilayer body of multiple thin films. The thin films are all transparent and have refractive indexes different from each other.

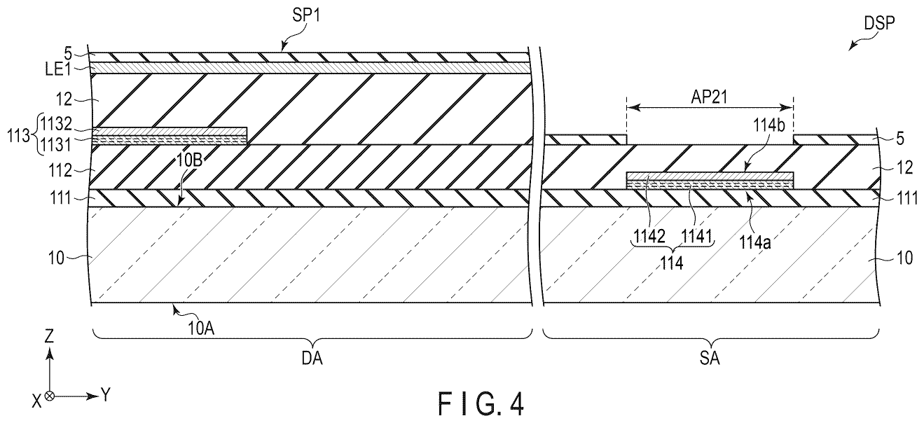

FIG. 4 is a cross-sectional view showing a configuration example of the display device DSP taken along the line 4-4 in FIG. 1. In FIG. 4, the subpixels SP2 and SP3 of the display area DA are omitted from the illustration. Here, the cross-sections of the display area DA and the peripheral area SA will be described.

In the display area DA, the main surface 10B of the substrate 10 is covered by an inorganic insulating layer 111. The inorganic insulating layer 111 includes various types of circuits such as the pixel circuit 1 and the like shown in FIG. 1, and various wiring lines such as scanning lines GL, signal lines SL, and power lines PL. In the display area DA, the inorganic insulating layer 111 is covered by an organic insulating layer 112. The inorganic insulating layer 111 and the organic insulating layer 112 are included in the circuit layer 11 shown in FIG. 3. In the display area DA, a conductive layer 113 is disposed on the organic insulating layer 112. The conductive layer 113 comprises a first conductive layer 1131 disposed on the organic insulating layer 112 and a second conductive layer 1132 disposed on the first conductive layer 1131. The conductive layer 113 is formed for each of the subpixels SP. The organic insulating layer 12 covers the organic insulating layer 112 and the conductive layer 113 in the display area DA. Further, in the display area DA, the lower electrode LE1 and the lower electrodes LE2 and LE3 (not shown) are disposed on the organic insulating layer 12. The peripheral portions of the lower electrodes LE1 and the lower electrodes LE2 and LE3 (not shown) are covered by the rib layer 5. Although not shown, in the display area DA, the partition 6, the multilayer stacked films FL1, FL2, and FL3, the sealing layers SE1, SE2, SE3, and 14, and the resin layers 13 and 15 are formed on the rib layer 5.

The lower electrode LE1 is electrically connected to the pixel circuit 1 of the subpixel SP1 via the conductive layer 113 of the subpixel SP1. The lower electrode LE2 is electrically connected to the pixel circuit 1 of the subpixel SP2 via the conductive layer 113 of the subpixel SP2. The lower electrode LE3 is electrically connected to the pixel circuit 1 of the subpixel SP3 via the conductive layer 113 of the subpixel SP3.

In the peripheral area SA, the main surface 10B of the substrate 10 is covered by the inorganic insulating layer 111. In the peripheral area SA, a base 114 is disposed on the inorganic insulating layer 111. The base 114 includes a first base portion 1141 disposed on the inorganic insulating layer 111 and a second base portion 1142 disposed on the first base portion 1141. The base 114 has a surface 114a facing the main surface 10B of the substrate 10 and a surface 114b on an opposite side to the surface 114a. The organic insulating layer 12 covers the inorganic insulating layer 111 and the base 114 in the peripheral area SA. In the peripheral area SA, the rib layer 5 is disposed on the organic insulating layer 12. In the peripheral area SA, the rib layer 5 has an aperture AP21 that overlaps the base 114 in plan view. Note that in the example shown in FIG. 4, no layer is formed on the rib layer 5 in the peripheral area SA, but the configuration is not limited to this.

The inorganic insulating layer 111 and the organic insulating layer 12 are, for example, disposed across the display area DA and the peripheral area SA.

The first conductive layer 1131 of the conductive layer 113 is formed, for example, of metal multilayer stacked films. The first conductive layer 1131 is a multilayer body comprising a first layer formed from a titanium-based material such as titanium or a titanium compound, a second layer formed on the first layer and made of an aluminum-based material such as aluminum or an aluminum compound, and a third layer formed on the second layer and made of a titanium-based material such as titanium or a titanium compound.

The second conductive layer 1132 of the conductive layer 113 is formed from a conductive material different from that of the first conductive layer 1131. The second conductive layer 1132 is formed, for example, from an oxide conductive material such as indium tin oxide (ITO).

The first base portion 1141 is formed, for example, of metal multilayer stacked films. The first base portion 1141 is a stacked body comprising a first layer formed of a titanium-based material such as titanium or a titanium compound, a second layer formed on the first layer and made of an aluminum-based material such as aluminum or an aluminum compound, and a third layer formed on the second layer and made of a titanium-based material such as titanium or a titanium compound.

The second base portion 1142 is formed from a conductive material different from that of the first base portion 1141. The second base portion 1142 is formed, for example, from an oxide conductive material such as indium tin oxide (ITO).

The first conductive layer 1131 and the first base portion 1141 may be formed from the same material in a single step. Further, the second conductive layer 1132 and the second base portion 1142 may be formed from the same material in a single step.

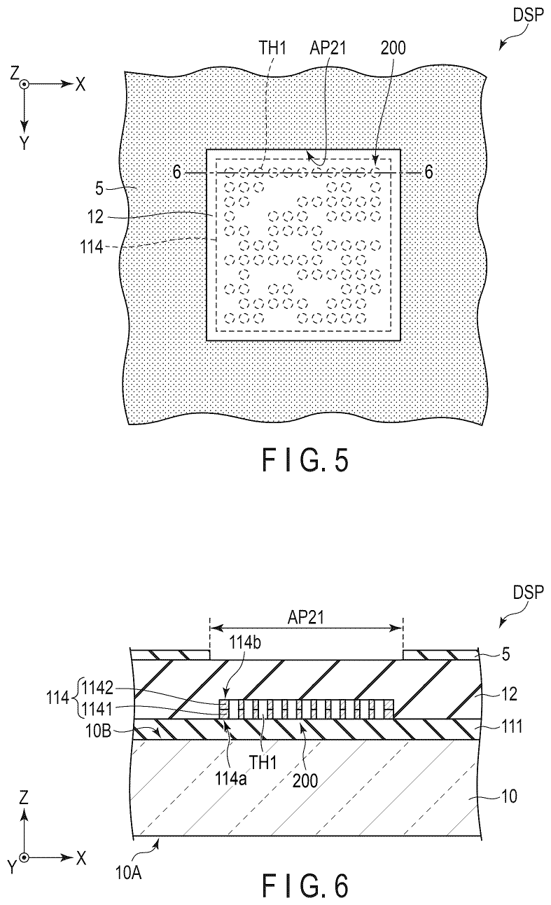

FIG. 5 is a plan view showing a configuration example of the peripheral area SA shown in FIG. 4. In FIG. 5, the rib layer 5 is indicated by dots. FIG. 6 is a cross-sectional view schematically showing the display device DSP taken along the line 6-6 in FIG. 5.

As shown in FIG. 5, the rib layer 5 has an aperture AP21 that overlaps the base 114 in plan view. In the aperture AP21, the organic insulating layer 12 is exposed from the rib layer 5.

The base 114 has a surface 114a facing the main surface 10B of the substrate 10 and a surface 114b on an opposite side to the surface 114a. The base 114 has, for example, a rectangular shape in plan view. In the example shown in FIGS. 5 and 6, the aperture AP21 has a rectangular shape larger than the base 114 in plan view, but the configuration is not limited to this.

The base 114 has identification information 200. The identification information 200 is formed, for example, as multiple through holes TH1 that penetrate the first base portion 1141 and the second base portion 1142 along the third direction Z, as shown in FIGS. 5 and 6. The multiple through holes TH1 are arranged, for example, in accordance with predetermined rules along the first direction X and the second direction Y, and form a two-dimensional code in plan view.

Note that the identification information 200 may be formed as multiple through holes that penetrate either one of the first base portion 1141 and the second base portion 1142. Alternatively, the identification information 200 may as well be formed as multiple recess portions formed on at least one of the surface 114a and surface 114b of the base 114. Further, the identification information 200 may as well be formed by changing the color of multiple locations on at least one of the surface 114a and surface 114b of the base 114.

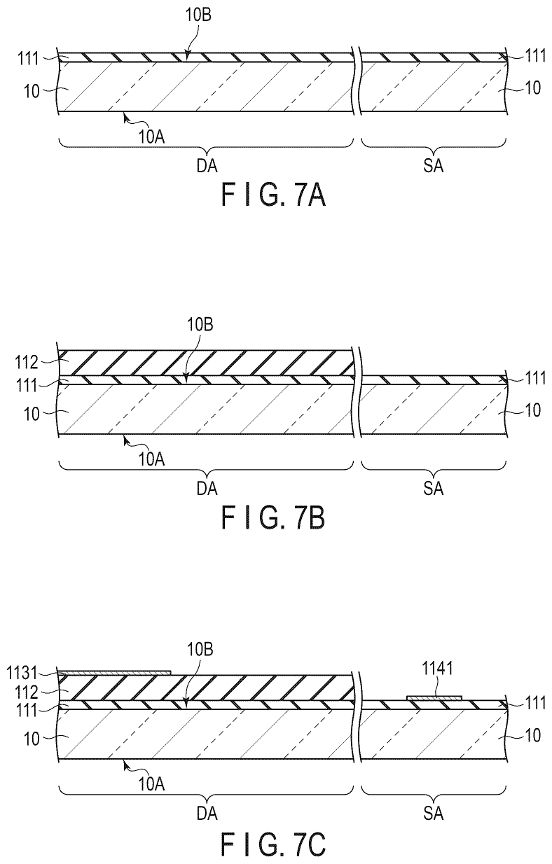

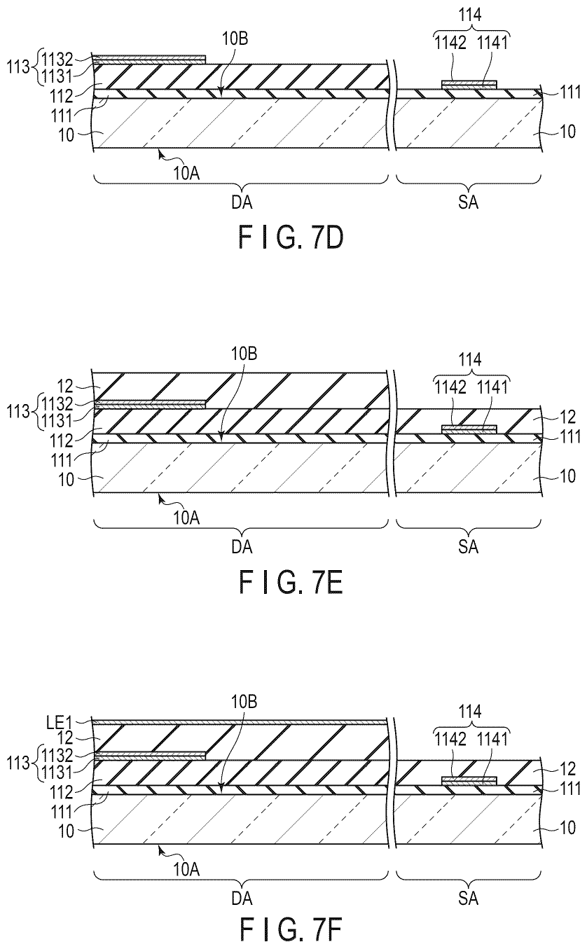

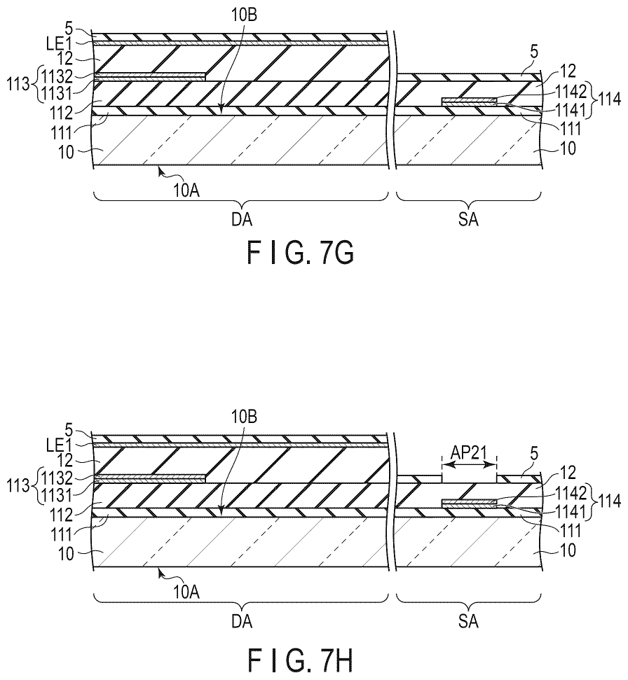

Next, an example of a method of manufacturing the display device DSP will be described. FIGS. 7A to 7H are schematic cross-sectional views each showing a respective step in the process of manufacturing the display device DSP.

First, as shown in FIG. 7A, the inorganic insulating layer 111 is formed on the main surface 10B of the substrate 10, over across the display area DA and the peripheral area SA. Next, as shown in FIG. 7B, the organic insulating layer 112 is formed on the inorganic insulating layer 111 in the display area DA.

After the step of forming the organic insulating layer 112, the first conductive layer 1131 is formed on the organic insulating layer 112 in the display area DA, as shown in FIG. 7C. Further, in the peripheral area SA, the first base portion 1141 is formed on the inorganic insulating layer 111. The first conductive layer 1131 and the first base portion 1141 may be formed from the same material collectively in one step.

After the step of forming the first conductive layer 1131 and the first base portion 1141, as shown in FIG. 7D, the second conductive layer 1132 is formed on the first conductive layer 1131 in the display area DA. Further, in the peripheral area SA, the second base portion 1142 is formed on the first base portion 1141. The second conductive layer 1132 and the second base portion 1142 may be formed from the same material collectively in one step. As a result, the conductive layer 113 is formed in the display area DA, and the base 114 is formed in the peripheral area SA.

After forming the second conductive layer 1132 and the second base portion 1142, as shown in FIG. 7E, the organic insulating layer 12 is formed to cover the organic insulating layer 112 and the conductive layer 113 of the display area DA, and the inorganic insulating layer 111 and the base 114 of the peripheral area SA. The organic insulating layer 12 may be formed over across the display area DA and the peripheral area SA.

After the step of forming the organic insulating layer 12, as shown in FIG. 7F, the lower electrodes LE1, LE2, and LE3 are formed on the organic insulating layer 12 in the display area DA. In FIG. 7F, the lower electrodes LE2 and LE3 are omitted from the illustration.

After forming the lower electrodes LE1, LE2, and LE3, as shown in FIG. 7G, the rib layer 5 is formed in the display area DA so as to cover the peripheral portions of the lower electrodes LE1 and the lower electrodes LE2 and LE3, which are not shown. Further, in the peripheral area SA, the rib layer 5 is formed on the organic insulating layer 12.

After forming the rib layer 5, as shown in FIG. 7H, the aperture AP21 is formed in the rib layer 5 in the peripheral area SA by patterning or the like. Note that the step of forming the aperture AP21 may be performed at any stage after the step of forming the rib layer 5. Further, note that the apertures AP11, AP12, and AP13 in the rib layer 5 of the display area DA may be formed at the same time as that of the aperture AP21 or may be formed in a separate step from the step of forming the aperture AP21.

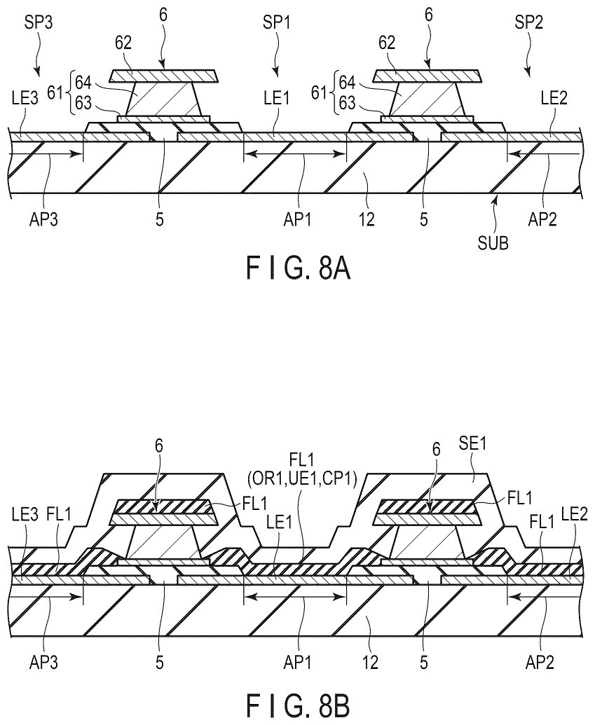

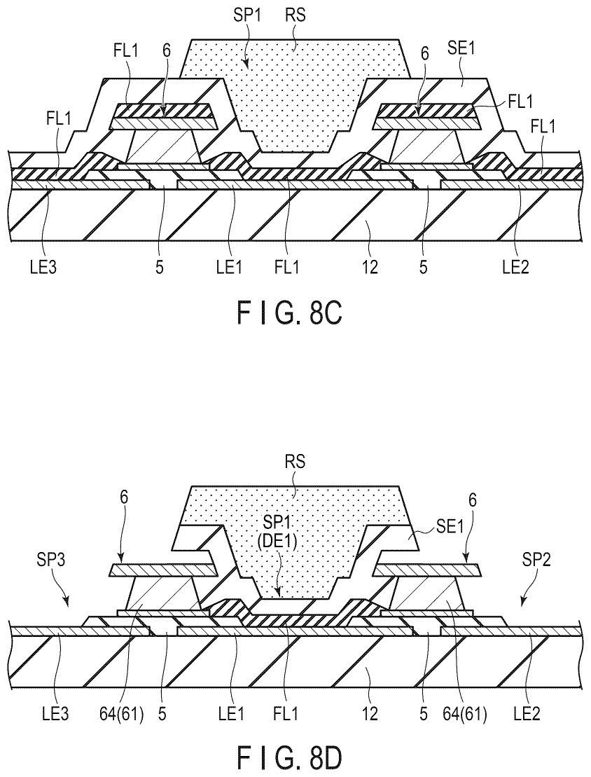

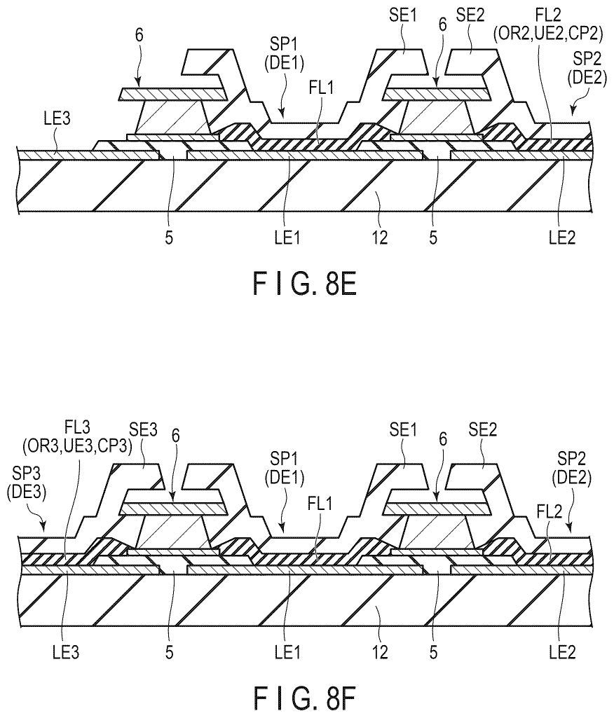

FIGS. 8A to 8F are schematic cross-sectional views each showing a respective step in the process of manufacturing the display device DSP. Here, the description will be made in connection with the display area DA. In FIGS. 8A to 8F, the substrate 10 and the circuit layer 11 are omitted from the illustration.

After the step of forming the rib layer 5, the partition 6 and the display elements DE are formed in the display area DA. First, as shown in FIG. 8A, the partition 6 is formed, which includes the lower portion 61 located above the rib layer 5 and the upper portion 62 located above the lower portion 61.

Next, the display element DE1 is formed. First, as shown in FIG. 8B, the organic layer OR1, the upper electrode UE1, and the cap layer CP1 are formed in this order on the lower electrode LE1 to form the multilayer stacked film FL1.

The organic layer OR1, the upper electrode UE1, and the cap layer CP1 are each formed by vapor deposition using the partition 6 as a mask. The multilayer stacked film FL1 is divided into multiple sections by the overhanging partition 6. The multilayer stacked film FL1 having such a configuration is formed on the lower electrode LE2 and the lower electrode LE3 as well.

After that, the sealing layer SE1 is formed on the multilayer stacked film FL1. The sealing layer SE1 is formed by chemical vapor deposition (CVD). The sealing layer SE1 continuously covers each of the divided sections of the multilayer stacked film FL1 and the partition 6.

Subsequently, as shown in FIG. 8C, a resist RS patterned into a predetermined shape is formed on the sealing layer SE1. The resist RS overlaps the subpixel SP1 and a part of the partition 6 surrounding it.

Then, as shown in FIG. 8D, etching is performed using the resist RS as a mask, and thus the sealing layer SE1 and the multilayer stacked film FL1 exposed from the resist RS are sequentially removed. As a result, the upper portion 62 of the partition 6 is exposed. In the subpixel SP1, the multilayer stacked film FL1 covered by the resist RS remains, while in the subpixel SP2, the lower electrode LE2 is exposed, and in the subpixel SP3, the lower electrode LE3 is exposed. The etching includes wet etching and dry etching performed in order on the sealing layer SE1, cap layer CP1, upper electrode UE1, and organic layer OR1. After these etching steps, the resist RS is removed. As a result, the display element DE1 is formed in the subpixel SP1.

Subsequently, as shown in FIG. 8E, the display element DE2 is formed. The procedure for forming the display element DE2 is similar to the procedure for forming the display element DE1. That is, the multilayer stacked film FL2 is formed on the lower electrode LE2, and the sealing layer SE2 is formed on the multilayer stacked film FL2. After that, a resist is formed on the sealing layer SE2, and the sealing layer SE2 and the multilayer stacked film FL2 are patterned by etching using the thus formed resist as a mask. After this patterning, the resist is removed. As a result, the display element DE2 is formed in the subpixel SP2, and the lower electrode LE3 of the subpixel SP3 is exposed.

Next, as shown in FIG. 8F, the display element DE3 is formed. The procedure for forming the display element DE3 is similar to that for forming the display element DE1. That is, the multilayer stacked film FL3 is formed on the lower electrode LE3, and the sealing layer SE3 is formed on the multilayer stacked film FL3. After that, a resist is formed on the sealing layer SE3, and the sealing layer SE3 and the stacked film stacked film FL3 are patterned by etching using the thus formed resist as a mask. After this patterning, the resist is removed. As a result, the display element DE3 is formed in the subpixel SP3.

Then, the resin layer 13, the sealing layer 14, and the resin layer 15 shown in FIG. 3 are sequentially formed in the display area DA. In this way, the display device DSP is completed.

Note that the above-provided manufacturing process is assumed on that the display element DE1 is formed first, followed by the display element DE2 formed next, and finally, the display element DE3. But the order of formation of the display elements DE1, DE2, and DE3 is not limited to that of this example.

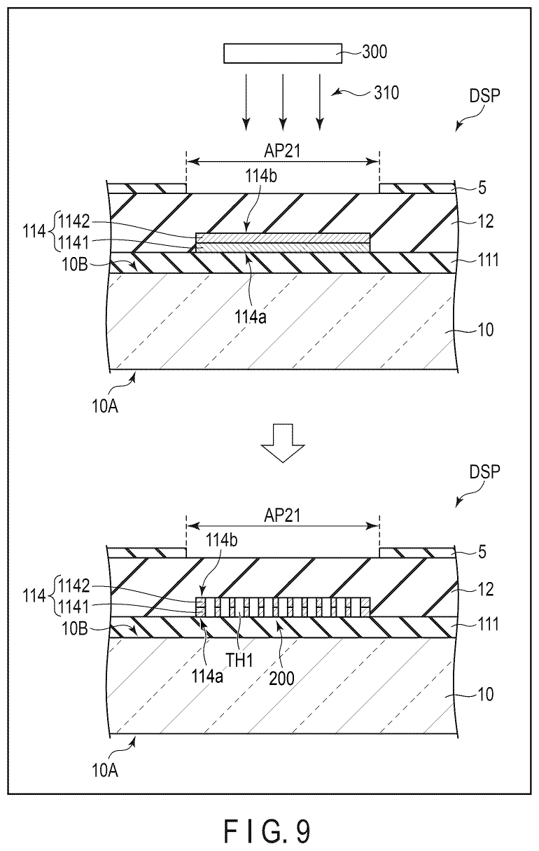

FIG. 9 is a cross-sectional view schematically showing the manufacturing process of the display device DSP. Here, the peripheral area SA is described.

Subsequently, the identification information 200 is formed on the base 114 of the peripheral area SA. As shown in FIG. 9, laser light 310 is irradiated from a laser irradiation device 300 toward the base 114. In the example shown in FIG. 9, the surface 114b of the base 114 and the laser irradiation device 300 are arranged so that they face each other.

The laser light 310 passes through the organic insulating layer 12 and forms the through hole TH1 that penetrates the first base portion 1141 and the second base portion 1142 along the third direction Z. In this way, the identification information 200 is formed on the base 114.

Although not shown, the surface 114a of the base 114 and the laser irradiation device 300 may be arranged to face each other so as to irradiate laser light onto the surface 114a. In this case, the laser light 310 passes through the substrate 10 and the inorganic insulating layer 111, thereby forming the through hole TH1 that penetrates the first base portion 1141 and the second base portion 1142 along the third direction Z.

Note that the step of forming the identification information 200 may be performed at any stage after the step of forming the base 114.

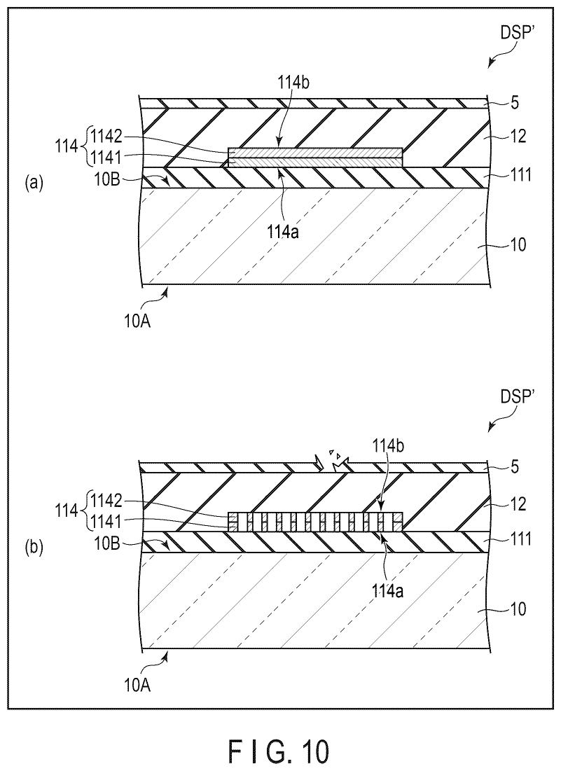

FIG. 10, including part (a) and part (b), is a cross-sectional view showing a display device DSP′ according to a comparative example. FIG. 10, part (a) is a cross-sectional view of the display device DSP′ in a stage before forming the identification information 200, and FIG. 10, part (b) is a cross-sectional view of the display device DSP′ in a stage after forming the identification information 200.

The display device DSP′ of the comparative example is different from the display device DSP of the embodiment in that the rib layer 5 does not have an aperture AP21 that overlaps the base 114 in plan view.

As shown in FIG. 10, in the display device DSP′ of the comparative example, the rib layer 5, which overlaps the base 114 in plan view, may be damaged by the laser light 310 from the laser irradiation device 300, causing at least a part of the rib layer 5 to peel off from the organic insulating layer 12. Such peeling of the rib layer 5 may undesirably cause reading errors when reading the identifying information 200 with a scanner or the like. Further, the peeled rib layer 5 may scatter and come into contact with terminals TE or the like, potentially causing connection failures in the display device DSP.

In the display device DSP according to this embodiment, the rib layer 5 has the aperture AP21 that overlaps the base 114 in plan view. With this configuration, it is possible to suppresses damage to the rib layer 5, which may be caused by the irradiation of the laser light 310, thereby preventing the rib layer 5 from peeling off from the organic insulating layer 12 or the detached rib layer 5 from scattering.

Thus, according to this embodiment, the decrease in the reliability of reading the identification information 200 can be suppressed. Further, the decrease in the reliability of the display device DSP can be suppressed.

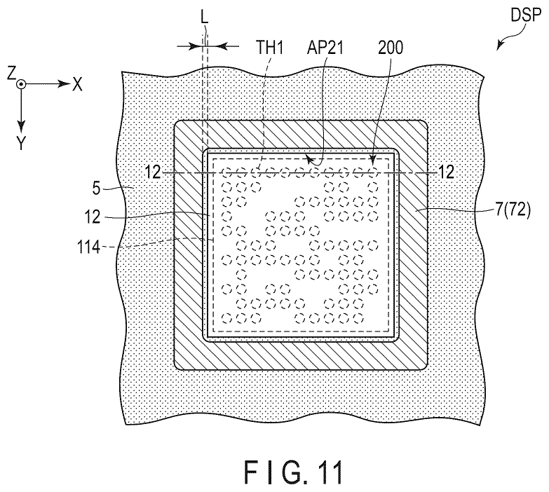

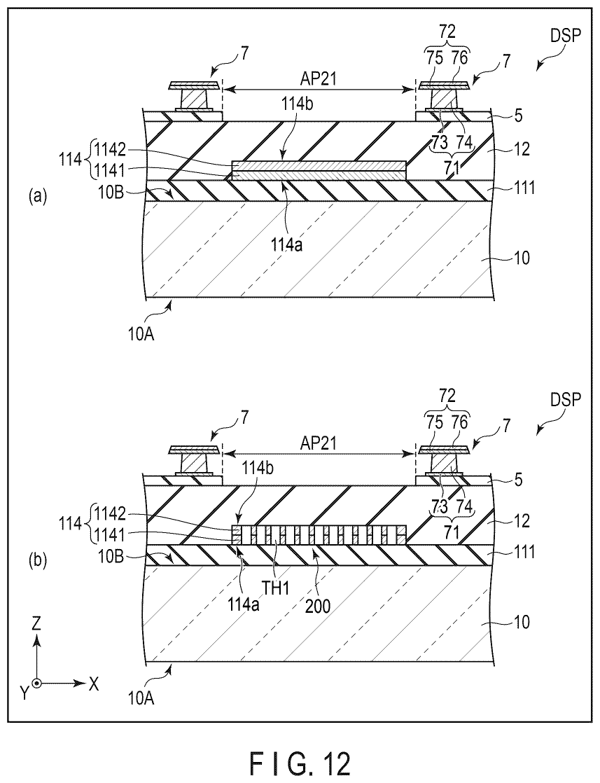

FIG. 11 is a plan view showing another configuration example of the peripheral area SA shown in FIG. 5. FIG. 12 is a cross-sectional view schematically showing the display device DSP taken along the line 12-12 in FIG. 11. FIG. 12, part (a) is a cross-sectional view of the display device DSP in a stage before the identification information 200 is formed, and FIG. 12, part (b) is a cross-sectional view of the display device DSP in a stage after the identification information 200 is formed.

The configuration example shown in FIG. 11 is different from the configuration example shown in FIG. 5 in that it further comprises a partition 7. The description of the configuration similar to that shown in FIG. 5 will be omitted by reference to the above-provided description. In FIG. 11, the partition 7 is indicated by diagonal lines. Additionally, in FIG. 11, the size of the partition 7 is enlarged and shown schematically.

As shown in FIG. 11, the partition 7 is formed on the rib layer 5 of the peripheral area SA and overlaps the rib layer 5 in plan view. Here, it is desirable that the partition 7 be formed on the rib layer 5 near the outer edge of the aperture AP21. The distance L from the outer edge of the aperture AP21 to the end portion of the upper portion 72 of the partition 7 is, for example, 5 μm to 60 μm.

The partition 7 is formed, for example, as shown in FIGS. 11 and 12, so as to surround the aperture AP21. It may as well be described that the partition 7 has an aperture that overlaps the aperture AP21. The shape of the partition 7 is not limited to that of the example shown. For example, multiple partitions 7 may be arranged so that they collectively surround the aperture AP21, and in this case, the multiple partitions 7 may be arranged to be apart from each other.

The partition 7 has a configuration similar to that of the partition 6 shown in FIG. 3, for example. As shown in FIG. 12, the partition 7 includes a lower portion 71 disposed on the rib layer 5 and an upper portion 72 disposed on the lower portion 71. The upper portion 72 has a width larger than that of the lower portion 71. Both end portions of the upper portion 72 protrude beyond the respective side surfaces of the lower portion 71.

In the example illustrated, the lower portion 71 includes a bottom layer 73 disposed on the rib layer and an axis layer 74 disposed on the bottom layer 73. For example, the bottom layer 73 is formed thinner than the axis layer 74. Both ends of the bottom layer 73 protrude from the side surfaces of the axis layer 74.

The upper portion 72 includes a first thin film 75 disposed above the axis layer 74 and a second thin film 76 disposed above the first thin film 75. Both end portions of the first thin film 75 and the second thin film 76 protrude from the respective side surfaces of the axis layer 74.

The lower portion 71 of the partition 7 is formed, for example, from a conductive material. The bottom layer 73 is formed, for example, from a titanium-based material such as titanium or a titanium compound. The axis layer 74 is formed from a material different from that of the bottom layer 73 and the upper portion 72, and is formed, for example, from an aluminum-based material such as aluminum or an aluminum compound.

The upper portion 72 of the partition 7 is formed, for example, from a conductive material, but may as well be formed from an insulating material. The upper portion 72 is formed from a material different from that of the lower portion 71. The first thin film 75 is formed, for example, from a titanium-based material such as titanium or a titanium compound. The second thin film 76 is formed, for example, from an oxide conductive material such as indium tin oxide (ITO).

The base 114 has identification information 200. The identification information 200 is formed as multiple through holes TH1 that penetrate the base 114 along the third direction Z, as shown in FIGS. 11 and 12, but the configuration is not limited to this.

In the manufacturing of the display device DSP, the partition 7 may be formed at any time after the rib layer 5 is formed, but it is preferable to form it before forming the display element DE. The partition 7 may be formed at the same time as that of the partition 6.

In the configuration example shown in FIG. 11, the partition 7 is formed on the rib layer 5, and thus the rib layer 5 is held in place by the partition 7, and therefore peeling of the rib layer 5 from the organic insulating layer 12 can be suppressed. Further, even in such a configuration example, advantageous effects similar to those presented in the configuration example shown in FIG. 5 can be obtained.

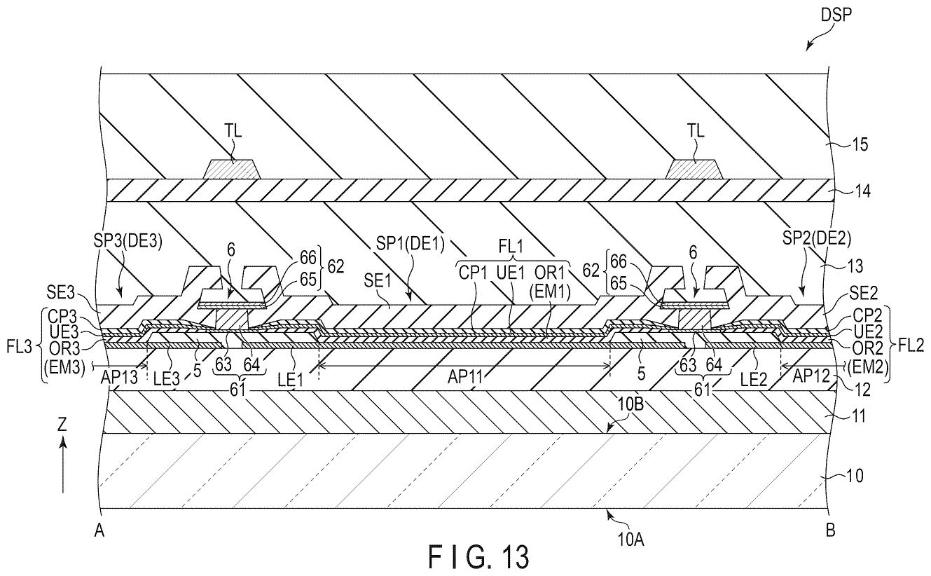

FIG. 13 is a cross-sectional view showing another configuration example of the display device DSP shown in FIG. 3. The description regarding the configuration similar to those shown in the configuration example of FIG. 3 is omitted by reference to the above-provided description.

The configuration example shown in FIG. 13 is different from the display device DSP shown in FIG. 3 in that it further comprises wiring lines TL. The wiring lines TL are formed on the sealing layer 14 and are located, for example, directly above the partition 6. The wiring lines TL having such a configuration functions, for example, as sensor wiring lines for detecting objects approaching the display device DSP. Note that the wiring lines TL are covered by the resin layer 15.

The wiring lines TL is formed from a metal material such as aluminum, titanium, or molybdenum. In one example, the wiring lines TL are each a multilayer stacked body comprising an aluminum layer sandwiched between a pair of titanium layers.

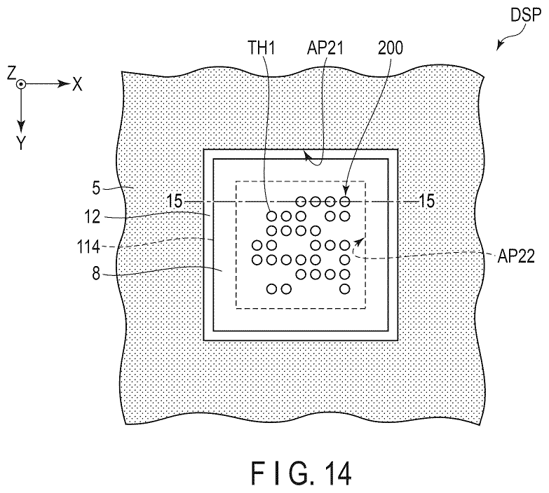

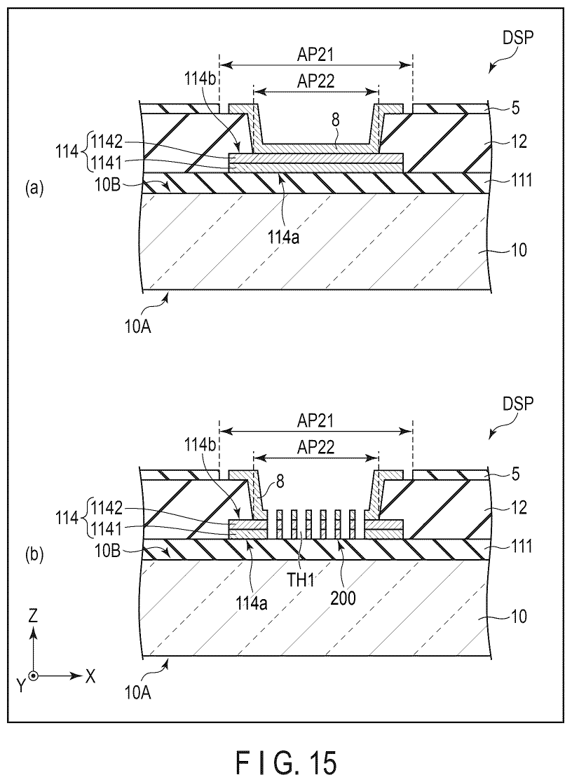

FIG. 14 is a plan view showing a configuration example of a peripheral area SA of the display device DSP shown in FIG. 13. FIG. 15, including part (a) and part (b), is a cross-sectional view schematically showing the display device DSP taken along the line 15-15 in FIG. 14. FIG. 15, part (a) is a cross-sectional view of the display device DSP in a stage before the identification information 200 is formed, and FIG. 15, part (b) is a cross-sectional view of the display device DSP in a stage after the identification information 200 is formed.

The configuration example shown in FIG. 14 is different from the configuration example shown in FIG. 5 in that it further includes a protective layer 8. The description of the configuration similar to that shown in FIG. 5 is omitted by reference to the above-provided description.

As shown in FIGS. 14 and 15, the organic insulating layer 12 has an aperture AP22 that overlaps the aperture AP21 in plan view. The aperture AP22 is made through to the base 114 along the third direction Z. In the aperture AP22, the surface 114b of the base 114 is exposed from the organic insulating layer 12.

The protective layer 8 is placed on the aperture AP22. The protective layer 8 is brought into contact with the surface 114b exposed from the organic insulating layer 12 in the aperture AP22. In the example shown in FIGS. 14 and 15, the protective layer 8 covers the organic insulating layer 12 between an edge portion of the aperture AP21 and an edge portion of the aperture AP22, and on a side surface of the aperture AP22. The protective layer 8 is formed from the same material as that of the wiring lines TL shown in FIG. 13, for example, collectively in one step.

At least one of the base 114 and the protective layer 8 has identification information 200. The identification information 200 is formed, for example, as multiple through holes TH1 that penetrate the base 114 and the protective layer 8 along the third direction Z in the aperture AP22, as shown in FIGS. 14 and 15. That is, the protective layer 8 comprises identification information 200 that overlaps the identification information 200 of the base 114.

In this configuration example as well, advantageous effects similar to those of the configuration example shown in FIG. 5 can be obtained.

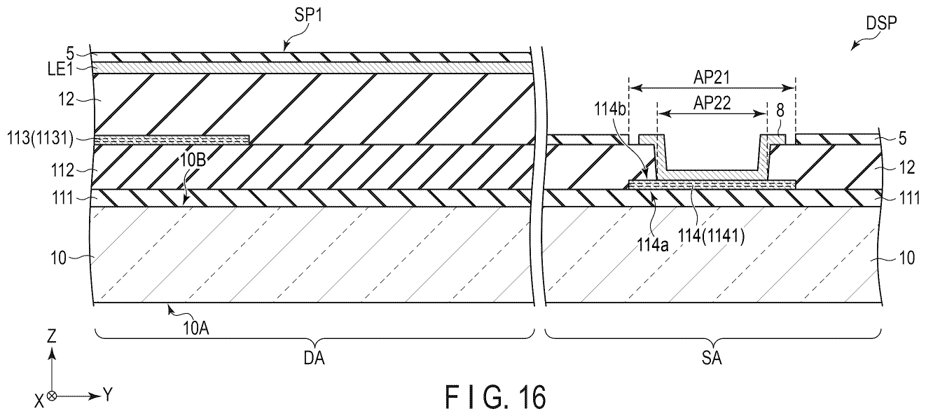

FIG. 16 is a cross-sectional view showing another configuration example of the display device DSP shown in FIG. 4.

The configuration example shown in FIG. 16 is different from the display device DSP shown in FIG. 4 in that the conductive layer 113 comprises only the first conductive layer 1131 and does not comprise the second conductive layer 1132, the base 114 comprises only the first base portion 1141 and does not comprise the second base portion 1142, and the device further comprises a protective layer 8.

The first conductive layer 1131 is disposed on the organic insulating layer 112 and covered by the organic insulating layer 12. The first base portion 1141 is disposed on the inorganic insulating layer 111 and brought into contact with the protective layer 8 in the aperture AP22.

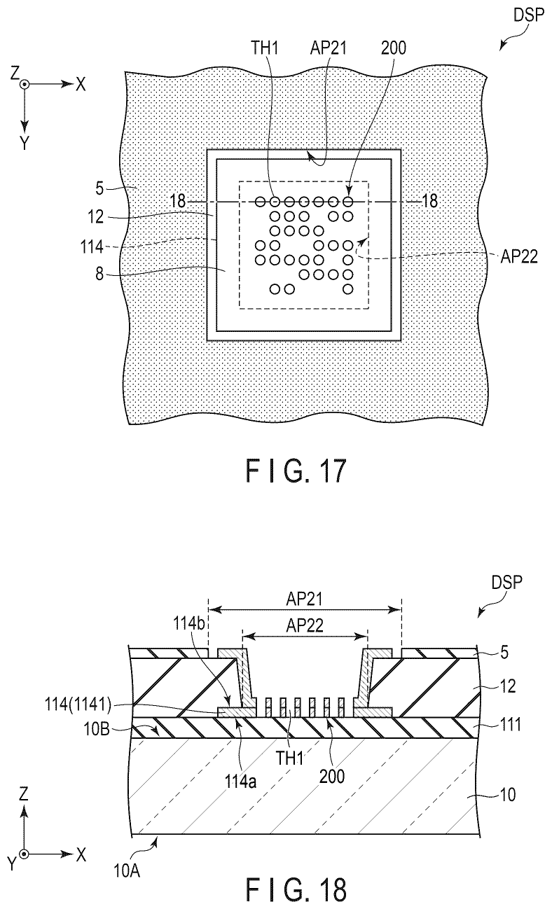

FIG. 17 is a diagram showing a configuration example of a peripheral area SA of the display device DSP shown in FIG. 16. FIG. 18 is a schematic cross-sectional view of the display device DSP taken along the line 18-18 in FIG. 17.

As shown in FIGS. 17 and 18, the organic insulating layer 12 has an aperture AP22 that overlaps the aperture AP21 in plan view. The aperture AP22 penetrates to the base 114. In the aperture AP22, the first base portion 1141 is exposed from the organic insulating layer 12.

The protective layer 8 is disposed on the aperture AP22. The protective layer 8 is brought into contact with the first base portion 1141 exposed from the organic insulating layer 12 in the aperture AP22.

At least one of the first base portion 1141 and the protective layer 8 has identification information 200. The identification information 200 is formed, for example, as shown in FIG. 18, as multiple through holes TH1 that penetrate the first base portion 1141 and the protective layer 8 along the third direction Z in the aperture AP22.

In this configuration example as well, advantageous effects similar to those of the configuration example shown in FIG. 5 can be obtained.

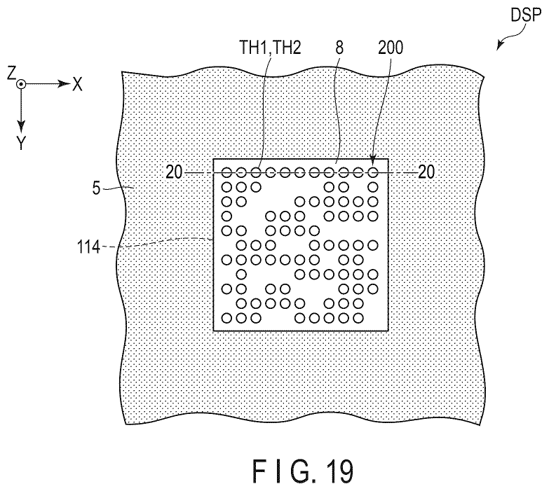

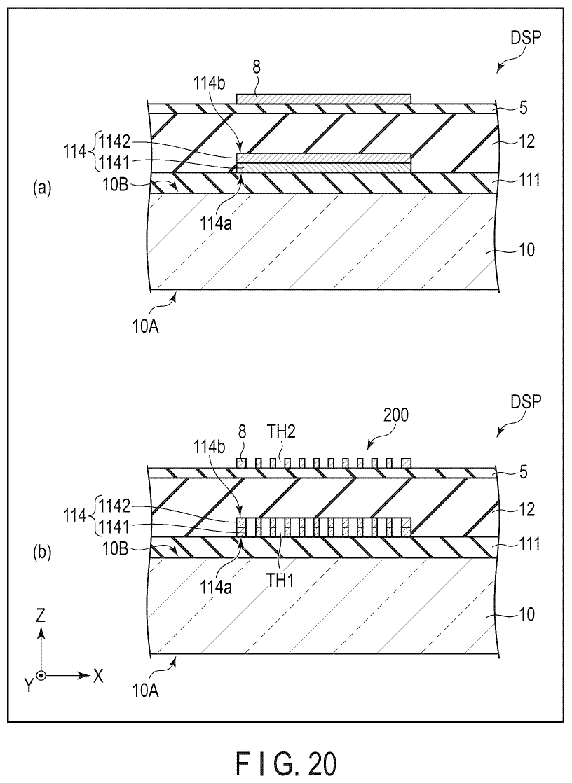

FIG. 19 is a diagram showing another configuration example of the peripheral area SA shown in FIG. 5. Further, FIG. 20, including part (a) and part (b), is a schematic cross-sectional view of the display device DSP taken along the line 20-20 in FIG. 19. FIG. 20, part (a) is a cross-sectional view of the display device DSP in a stage before the identification information 200 is formed, and FIG. 20, part (b) is a cross-sectional view of the display device DSP in a stage after the identification information 200 is formed.

The configuration example shown in FIG. 19 is different from the configuration example shown in FIG. 5 in that the rib layer 5 does not have an aperture AP21 and a protective layer 8 is formed on the rib layer 5. The description of the configuration similar to that shown in FIG. 5 is omitted by reference to the above-provided description.

As shown in FIGS. 19 and 20, the protective layer 8 is disposed on the rib layer 5 in the peripheral area SA. The protective layer 8 overlaps the base 114 in plan view. In the example shown in FIG. 19, the protective layer 8 has a rectangular shape of the same size as that of the base 114, but the configuration is not limited to this.

At least one of the base 114 and the protective layer 8 has identification information 200. The identification information 200 is formed, for example, as multiple through holes TH1 penetrating the base 114 in the third direction Z and multiple through holes TH2 penetrating the protective layer 8 in the third direction Z, as shown in FIG. 20. Each of the multiple through holes TH1 and each respective one of the multiple through holes TH2 overlap each other in plan view. In other words, the identification information 200 of the protective layer 8 overlaps the identification information 200 of the base 114.

The multiple through holes TH1 and the multiple through holes TH2 are arranged along the first direction X and the second direction Y according to a predetermined rule, for example, as shown in FIG. 19, and form a two-dimensional code in plan view.

In the configuration example shown in FIG. 19, a protective layer 8 that overlaps the base 114 is provided on the rib layer 5. In this way, the rib layer 5, which overlaps with the base 114 in plan view, is protected by the protective layer 8. Therefore, during the formation of the identification information 200, even if the rib layer 5 is damaged by irradiation of laser light, the peeling off of the rib layer 5 from the organic insulating layer 12 can be suppressed. Further, even if the rib layer 5 peels off, the scattering of the peeled rib layer 5 can be suppressed.

Thus, even in the configuration example shown in FIG. 19, it is possible to suppress a decrease in the reliability of reading the identification information and to suppress a decrease in the reliability of the display device DSP.

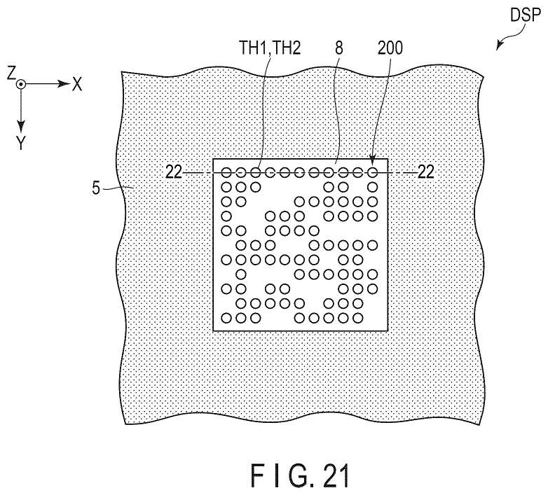

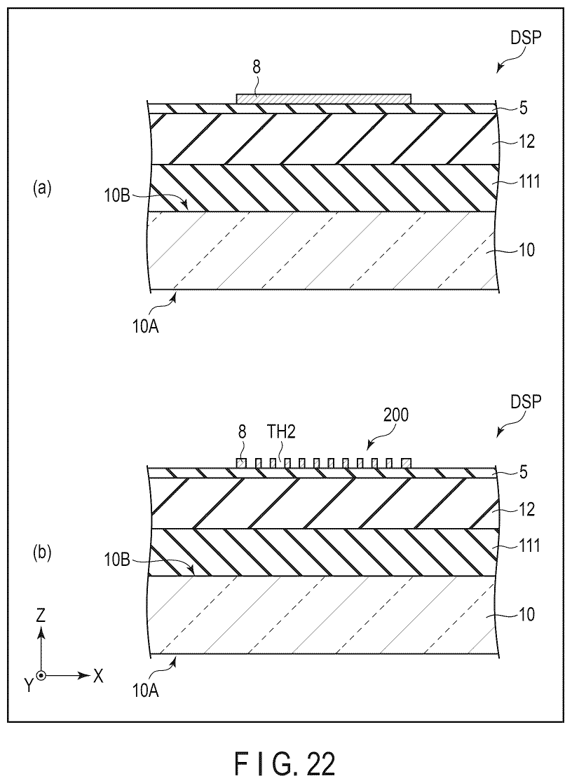

FIG. 21 is a cross-sectional view showing another configuration example of the peripheral area SA shown in FIG. 19. FIG. 22, including part (a) and part (b), is a schematic cross-sectional view of the display device DSP taken along the line 22-22 in FIG. 21. FIG. 22, part (a) is a cross-sectional view of the display device DSP in a stage before the identification information 200 is formed, and FIG. 22, part (b) is a cross-sectional view of the display device DSP in a stage after the identification information 200 is formed.

The configuration example shown in FIG. 21 is different from the configuration example shown in FIG. 19 in that the display device DSP does not comprise a base 114. The description of the configuration similar to that shown in FIG. 19 is omitted by reference to the above-provided description. As shown in FIGS. 21 and 22, the protective

layer 8 is disposed on the rib layer 5. The protective layer 8 has identification information 200. The identification information 200 is formed, for example, as multiple through holes TH2 that penetrate the protective layer 8 along the third direction Z, as shown in FIGS. 21 and 22.

In this configuration example as well, advantageous effects similar to those of the configuration example shown in FIG. 19 can be obtained.

As described above, according to the present embodiment, a method of manufacturing a display device, which can suppress a decrease in reliability can be provided.

Based on the methods of manufacturing a display device, described above as embodiments of the invention, a person having ordinary skill in the art may achieve manufacturing methods with arbitral design changes; however, as long as they fall within the scope and spirit of the present invention, all of such manufacturing methods are encompassed by the scope of the present invention.

A skilled person would conceive various changes and modifications of the present invention within the scope of the technical concept of the invention, and naturally, such changes and modifications are encompassed by the scope of the present invention. For example, if a skilled person adds/deletes/alters a structural element or design to/from/in the above-described embodiments, or adds/deletes/alters a step or a condition to/from/in the above-described embodiment, as long as they fall within the scope and spirit of the present invention, such addition, deletion, and altercation are encompassed by the scope of the present invention.

Furthermore, regarding the present embodiments, any advantage and effect those will be obvious from the description of the specification or arbitrarily conceived by a skilled person are naturally considered achievable by the present invention.

What is claimed is:

1. A display device comprising:
a substrate;
an inorganic insulating layer disposed above the substrate and disposed over a display area which displays images and a peripheral area on an outer side of the display area;
an organic insulating layer disposed on the inorganic insulating layer;
a rib layer disposed above the organic insulating layer and formed of an inorganic material;
a lower electrode disposed on the organic insulating layer in the display area and including a peripheral portion covered by the rib layer;
an organic layer including a light emitting layer disposed on the lower electrode;
an upper electrode covering the organic layer;
a first partition including a first lower portion disposed on the rib layer and a first upper portion protruding from a side surface of the first lower portion in the display area; and
a base disposed between the inorganic insulating layer and the organic insulating layer in the peripheral area, and having identification information,
wherein the rib layer includes a first aperture that overlaps the base in the peripheral area in plan view.

2. The display device of claim 1, further comprising:
a second partition including a second lower portion disposed on the rib layer and a second upper portion protruding from a side surface of the second lower portion in the peripheral area.

3. The display device of claim 2, wherein
the second partition surrounds the first aperture in plan view.

4. The display device of claim 1, wherein
the organic insulating layer comprises a second aperture that overlaps the first aperture in plan view and penetrates to the base in the peripheral area, and
the display device further comprises a protective layer disposed in the second aperture and brought into contact with the base.

5. The display device of claim 4, wherein
the protective layer has identification information that overlaps with the identification information of the base in plan view.

6. A display device comprising:
a substrate;
an inorganic insulating layer disposed above the substrate and disposed over a display area which displays images and a peripheral area on an outer side of the display area;
an organic insulating layer disposed on the inorganic insulating layer;
a rib layer disposed above the organic insulating layer and formed of an inorganic material;
a lower electrode disposed on the organic insulating layer in the display area and including a peripheral portion covered by the rib layer;
an organic layer including a light emitting layer disposed on the lower electrode;
an upper electrode covering the organic layer;
a first partition including a first lower portion disposed on the rib layer and a first upper portion protruding from a side surface of the first lower portion in the display area; and
a protective layer disposed above the rib layer in the peripheral area and having identification information.

7. The display device of claim 6, further comprising:
a base disposed between the inorganic insulating layer and the organic insulating layer in the peripheral area, and having identification information,
wherein
the protective layer overlaps the base in plan view, and
the identification information of the protective layer overlaps the identification information of the base in plan view.

8. The display device of claim 1, wherein
the base comprises a first base portion formed of metal multilayer stacked films.

9. The display device of claim 8, wherein
the base further comprises a second base portion disposed on the first base portion, and
the second base portion is formed of an oxide conductive material different from that of the first base portion.

10. The display device of claim 7, wherein
the base comprises a first base portion formed of metal multilayer stacked films.

11. The display device of claim 10, wherein
the base further comprises a second base portion disposed on the first base portion, and
the second base portion is formed of an oxide conductive material different from that of the first base portion.

12. The display device of claim 1, wherein
the identification information of the base is a plurality of through holes formed in the base.

13. The display device of claim 12, wherein
the base comprises a first base portion formed of metal multilayer stacked films, and a second base portion formed of an oxide conductive material different from that of the first base and disposed on the first base portion, and
the plurality of through holes are through holes that penetrate at least one of the first base portion and the second base portion.

14. The display device of claim 7, wherein
the identification information of the base is a plurality of through holes formed in the base.

15. The display device of claim 14, wherein
the base comprises a first base portion formed of metal multilayer stacked films, and a second base portion formed of an oxide conductive material different from that of the first base and disposed on the first base portion, and
the plurality of through holes are through holes that penetrate at least one of the first base portion and the second base portion.

16. The display device of claim 6, wherein
the identification information of the base is a plurality of through holes formed in the base.

17. The display device of claim 5, wherein
the base comprises a first base portion formed of metal multilayer stacked films, and
the first base portion and the protective layer are stacked in this order.

18. The display device of claim 5, wherein
the base comprises a first base portion formed of metal multilayer stacked films, and a second base portion formed of an oxide conductive material different from that of the first base and disposed on the first base portion, and
the first base portion, the second base portion, and the protective layer are stacked in this order.
